(19) United States
(12) Patent Application Publication
(10) Pub. No.: US 2012/0007158 A1
(43) Pub. Date: Jan. 12, 2012

(54) NON-VOLATILE MEMORY TRANSISTOR HAVING DOUBLE GATE STRUCTURE

(75) Inventors: Sung Min YOON, Daejeon (KR); Shin Hyuk Yang, Gyeonggi-do (KR); Chun Won Byun, Daejeon (KR); Min Ki Ryu, Seoul (KR); Soon Won Jung, Daejeon (KR)

(73) Assignee: ELECTRONICS AND TELECOMMUNICATIONS RESEARCH INSTITUTE, Daejeon (KR)

(21) Appl. No.: 13/173,625

(22) Filed: Jun. 30, 2011

(30) Foreign Application Priority Data
Jul. 12, 2010 (KR) 10-2010-0066837

(51) Int. Cl. H01L 27/088

(52) U.S. Cl. 257/295; 257/E27.06

(57) ABSTRACT

Provided is a non-volatile memory transistor having a double gate structure, including a first gate electrode formed on a substrate and to which an operating voltage is applied, a first gate insulating layer formed on the first gate electrode, source and drain electrodes formed on the first gate insulating layer at predetermined intervals, a channel layer formed on the first gate insulating layer between the source and drain electrodes, a second gate insulating layer formed on the channel layer, and a second gate electrode formed on the second gate insulating layer and connected to the first gate electrode such that the operating voltage is applied thereto. Accordingly, a turn-on voltage of the memory transistor can be easily controlled.

### CROSS-REFERENCE TO RELATED APPLICATION

This application claims priority to and the benefit of Korean Patent Application No. 10-2010-0066837, filed Jul. 12, 2010, the disclosure of which is incorporated herein by reference in its entirety.

### BACKGROUND

1. Field of the Invention

The present invention relates to a non-volatile memory device having a double gate structure, and more particularly, to a non-volatile memory transistor having a double gate structure, which is capable of easily controlling a turn-on voltage.

2. Discussion of Related Art

The conventional electronic industry has been developed by the advancement in technologies of materials and devices based on silicon, that is, silicon electronics. However, a material based on the silicon electronics is not suitable for certain applications since it is rigid, brittle, and opaque in a visible wavelength range.

For these reasons, to overcome such limits of the silicon electronics, flexible electronics for manufacturing electronic devices and systems on a flexible substrate, and transparent electronics for manufacturing electronic devices and systems on a transparent substrate have been suggested. Currently, in these fields, research on developing various applications such as sensors, displays, electronic circuits, and batteries is in progress.

Particularly, in the flexible and transparent electronics, technologies for thin film transistors and transparent and flexible displays using the thin film transistor as a backplane driver are being rapidly developed. While technologies for thin film transistors and displays to display and process data are being actively developed, technology for data storing devices to store data, that is, technology for memory devices, is relatively behind in the field.

In the flexible and transparent electronics, if a memory device can be built in a system, the functionality of the system can be greatly improved, power consumption can be reduced, and production cost can be reduced. Requirements for a memory device used in a flexible and transparent electronics system will be described below:

The first requirement is non-volatility of a memory in terms of storage type. Since the system has a high chance to be a design-oriented application whose mobile function is emphasized, rather than a stand-alone electronic device to which power is always supplied, the system preferably has a non-volatile data storing function to prolong a lifespan of a battery and ensure a capability of storing high capacity data.

The second requirement is a low operating voltage of a memory device. If only transparency and flexibility are emphasized so that an operating voltage required to operate a memory device is too high, the high operating voltage causes an increase in power consumption of the entire system, and thus necessity of a built-in memory device in a system or circuit is lost.

The third requirement is a decreased size of a memory device. A memory device to be used in the electronics system may simply store data and further reduce power consumption as a built-in memory device in the system. Thus, the reduction in size of the memory device is preferable to reduce the size of the entire system.

The fourth requirement is the operating stability of a memory device, which is required to operate a system of the memory device. In the case of a non-volatile memory device, the following operating stabilities are required. First, resistance to a repeated write operation, that is, an excellent rewrite operating characteristic is required. Second, the characteristic of long-term retention of stored data, that is, an excellent retention operating characteristic is required. Third, a characteristic of not losing stored data in a high temperature and humidity environment, that is, excellent environmental resistance is required. It is not necessary for the memory device required for the electronics to satisfy high performance operating reliability as high as required in the conventional silicon electronics, but only to satisfy the operating reliability required in a desired application.

Accordingly, to provide the structure of a non-volatile memory device as a thin film transistor, which meets the above-described requirements and has transparency and flexibility, and a method of manufacturing the same, the conventional art suggests the structure and operating principle of a memory thin film transistor having the following features:

The first feature is to use an oxide semiconductor thin film as a material for a channel in a thin film transistor. The oxide semiconductor is transparent in a visible wavelength range because of a high energy bandgap, and thus widely researched as a material for a channel to provide the thin film transistor in the flexible and transparent electronics.

The second feature is to use an organic ferroelectric thin film as a material for a gate insulating layer in the thin film transistor. An attempt to use the transistor as a non-volatile memory device by forming a gate insulating layer using a ferroelectric thin film has been studied for several years in the conventional silicon electronics. Here, the conventional silicon electronics normally used an oxide-based ferroelectric thin film. However, since the oxide-based ferroelectric thin film is generally crystallized at 500° C. or more, it causes a problem in terms of process consistency when being applied to a flexible and transparent thin film transistor generally manufactured at 300° C. or less. On the other hand, since an organic ferroelectric thin film can be crystallized at a low temperature and easily formed by a solution-mediated coating method, the conventional flexible transparent thin film transistor uses an organic ferroelectric thin film as a material for a gate insulating layer.

The third feature is to operate a memory by changing a turn-on voltage of a thin film transistor according to an application direction of a voltage using a residual polarization characteristic of the organic ferroelectric gate insulating layer. That is, the memory operation is implemented using two states: when residual polarization is aligned in a semiconductor channel direction by applying a positive voltage to the organic ferroelectric gate insulating layer, a great amount of drain current flows in the thin film channel including an oxide semiconductor generally classified as an n-type material due to a field effect. On the other hand, when residual polarization is aligned in a direction opposite to that of the semiconductor channel by applying a negative voltage to the organic ferroelectric gate insulating layer, almost no drain current flows in the oxide semiconductor thin film channel. Such an operating principle has an advantage in design of a device due to physical predictability and accuracy, unlike the operating principle of the flexible or transparent electronics memory device implemented in different ways.

However, the conventional non-volatile memory device having the above-described features has the following problems:

First, a turn-on voltage of the conventional non-volatile memory device is difficult to control. It is noted that a turn-on voltage of a field effect transistor generally used in the silicon electronics can be designed and controlled using various methods, for example, adjusting an impurity concentration of a semiconductor channel layer or a bias voltage of a semiconductor substrate, and changing a work function of a gate electrode.

However, in the thin film transistor using an oxide semiconductor as a semiconductor channel layer, it is difficult to accurately control a carrier concentration of the oxide semiconductor thin film, modulate a carrier concentration of a channel surface by doping, and control a turn-on voltage of the transistor because a difference in work function between the gate electrode and the semiconductor surface is not suitably reflected in the turn-on voltage when the gate electrode is changed. These problems are also caused in a common driving thin film transistor as well as the memory thin film transistor.

Particularly, when an n-type oxide semiconductor is used as a semiconductor channel layer, it is highly possible that a turn-on voltage defined as a voltage at which a drain current starts flowing from an off operation level of a transistor is formed in a negative voltage region. Thus, additional problems are caused, which will be described with reference to FIG. 1.

Second, the conventional memory thin film transistor has a low writing speed. The conventional memory thin film transistor uses an organic ferroelectric thin film as a gate insulating layer, so that about 100 msec or more of a writing voltage should be applied, and generally the writing voltage is applied at a width by seconds. For a stable write operation, the width and size of the writing voltage have a close relationship with each other, and using a high operating voltage condition, that is, as an application time or level of the writing voltage is increased, an operating speed can be raised. However, the increase in operating voltage alone is not preferable in terms of reducing power consumption and ensuring operating reliability of the device.

Third, the conventional memory thin film transistor cannot meet requirements of the flexible and transparent electronics system. The flexible and transparent electronics system requires a memory thin film transistor having performances capable of contributing low power consumption and high functionality of the system as a transistor which is built in the system to store data. That is, a memory thin film transistor having a high driving current, a low subthreshold swing (SS), and high field effect mobility is preferable, but the conventional memory thin film transistor does not meet such requirements.

Hereinafter, the first problem of the conventional memory thin film transistor will be described with reference to the accompanying drawing.

FIG. 1 is a graph showing drain current versus gate voltage of a conventional memory thin film transistor according to a difference in turn-on voltage of the transistor. Referring thereto, additional problems caused when the turn-on voltage is generated in a negative voltage region will be described.

First, an operating characteristic of a memory array is degraded, and power consumption of the entire system is increased. As shown in the graph, when the turn-on voltage is generated in the negative voltage region, although a gate voltage is maintained as 0V in an off-state memory, a considerable amount of drain current flows. Thus, an operating margin of the memory array is reduced, and the power consumption of the entire system is increased.

Second, the entire memory array has a complicated driving circuit structure. As shown in the graph, when the turn-on voltage is generated in the negative voltage region, an on-operating voltage for an on-write operation (e.g., storing data “1”) of the memory thin film transistor and an off-operating voltage for an off-write operation (e.g., storing data “0”) of the memory thin film transistor are highly likely to be asymmetrically set in the positive voltage region and the negative voltage region, and thus the structure of the memory driving circuit becomes complicated. Further, to maximize the operating margin of the memory array, a read operation should be performed when a predetermined negative voltage is applied to a gate, which is not preferable in terms of designing and driving the memory array.

Third, a retention characteristic of the memory thin film transistor is degraded. A memory thin film transistor of a non-volatile memory device stores data when a turn-on voltage is changed due to a write voltage applied to the gate, and the stored data should not be corrupted as time passes. Further, the stored data is read using a difference in drain current value flown by a read voltage applied to a gate of the memory thin film transistor, and the read voltage should be set to have the maximum difference in drain current value according to a data storage state during the read operation, that is, the maximum difference in drain current value when data “0” is stored and data “1” is stored. However, when an excessive turn-on voltage of the memory thin film transistor is generated in the negative voltage region, a significantly large amount of negative voltage should be applied as the read voltage during the read operation. However, this generates an internal electric field, and the data retention characteristic of the memory thin film transistor is degraded.

### SUMMARY OF THE INVENTION

The present invention is directed to a non-volatile memory thin film transistor having a double gate structure, which includes a first gate electrode to which a control voltage is applied to control a turn-on voltage of the transistor and a second gate electrode to which an operating voltage is applied when the control voltage is applied to the first gate electrode.

One aspect of the present invention provides a non-volatile memory transistor having a double gate structure, including: a first gate electrode formed on a substrate and to which an operating voltage is applied; a first gate insulating layer formed on the first gate electrode; source and drain electrodes formed on the first gate insulating layer at predetermined intervals; a channel layer formed on the first gate insulating layer between the source and drain electrodes; a second gate insulating layer formed on the channel layer; and a second gate electrode formed on the second gate insulating layer and connected to the first gate electrode such that the operating voltage is applied thereto.

Another aspect of the present invention provides a non-volatile memory transistor having a double gate structure, including: a first gate electrode formed on a substrate and to which a control voltage for controlling a turn-on voltage of the transistor is applied; a first gate insulating layer formed on the first gate electrode; source and drain electrodes formed on the first gate insulating layer at predetermined intervals; a channel layer formed on the first gate insulating layer between the source and drain electrodes; a second gate insulating layer formed on the channel layer; and a second gate electrode formed on the second gate insulating layer and to which an operating voltage is applied when the control voltage is applied to the first gate electrode.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a graph showing drain current versus gate voltage of a conventional memory thin film transistor;

FIG. 2A is a cross-sectional view of a non-volatile memory thin film transistor having a double gate structure according to a first exemplary embodiment of the present invention;

FIG. 2B is a cross-sectional view of a non-volatile memory thin film transistor having a double gate structure according to a second exemplary embodiment of the present invention;

FIGS. 3A to 3G are cross-sectional views illustrating a method of manufacturing the non-volatile memory thin film transistor having a double gate structure according to the first exemplary embodiment of the present invention;

FIGS. 4A to 4D are cross-sectional views illustrating a method of manufacturing the non-volatile memory thin film transistor having a double gate structure according to the second exemplary embodiment of the present invention;

FIG. 5 is a graph showing the relationship between a drain current and a gate voltage relative to a difference in turn-on voltage of the transistor in a memory thin film transistor having a double gate structure manufactured according to an exemplary embodiment of the present invention;

FIGS. 6A and 6B are a circuit diagram and a timing diagram, which illustrate a method of driving the memory thin film transistor having a double gate structure according to the first exemplary embodiment of the present invention;

FIGS. 7A and 7B are a circuit diagram and a timing diagram, which illustrate a method of driving the memory thin film transistor having a double gate structure according to the second exemplary embodiment of the present invention; and

FIGS. 8A and 8B are graphs showing the relationship between a gate voltage and a drain current of a memory thin film transistor having a double gate structure according to an exemplary embodiment of the present invention.

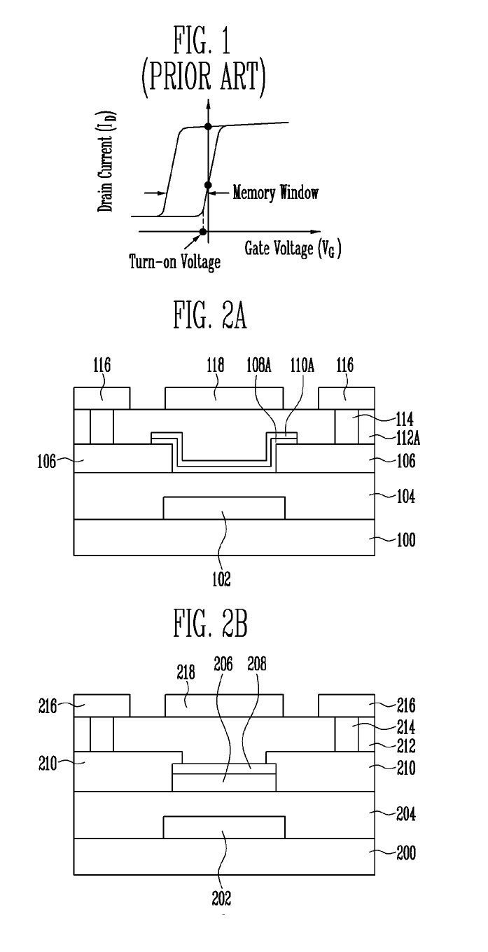

### DETAILED DESCRIPTION OF EXEMPLARY EMBODIMENTS

Hereinafter, exemplary embodiments of the present invention will be described in detail. However, the present invention is not limited to the embodiments disclosed below, but can be implemented in various forms. For clarity, a part that is not related to the description of the present invention will be omitted, and similar part will be represented by a similar reference mark throughout the specification. Throughout the specification, when a part “includes” or “comprises” a component, the part may include, not remove, another element, unless otherwise defined. In addition, the term “part” or “unit” used herein means a unit processing at least one function or operation.

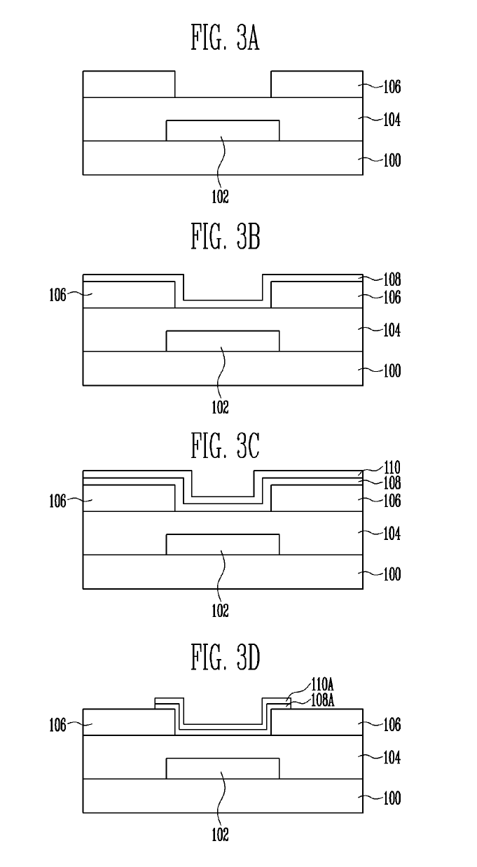

FIG. 2A is a cross-sectional view of a non-volatile memory thin film transistor having a double gate structure according to a first exemplary embodiment of the present invention, in which a channel layer is formed after source and drain electrodes are formed.

As described above, the non-volatile memory thin film transistor having a double gate structure according to the first exemplary embodiment of the present invention includes a first gate electrode 102 formed on a substrate 100, a first gate insulating layer 104 formed on the first gate electrode 102, source and drain electrodes 106 formed on the first gate insulating layer 104 at predetermined intervals, a channel layer 108A formed on the first gate insulating layer 104 between the source and drain electrodes 106, a second gate insulating layer 112A formed on the channel layer 108A, and a second gate electrode 118 formed on the second gate insulating layer 112A. Source and drain electrode pads 116 connected to the source and drain electrodes 106 by contact plugs 114 passing through the passivation layer 110A and the second gate insulating layer 112A formed on the channel layer 108A may be further included.

The substrate 100 may be formed of a material having flexibility and transparency, or in some cases, a material having one of these two characteristics. For example, the substrate 100 may be a glass substrate or a plastic substrate.

The first gate electrode 102 may be formed of a transparent conductive thin film. For example, the first gate electrode 102 may be formed of a conductive oxide material, such as indium-tin-oxide (ITO) or a material having sufficiently high conductivity and transparency like ITO. In some cases, according to the characteristic required for an application system of the memory thin film transistor suggested by the present invention, the first gate electrode 102 may be formed of a metal thin film used to manufacture a conventional thin film transistor.

The first gate insulating layer 104 may be formed of an oxide insulator thin film. For example, the first gate insulating layer 104 may be formed of a silicon-based insulating layer such as a silicon oxide (SiO₂) layer, a silicon nitride (SiNx) layer or a silicon oxynitride (SiON) layer, an aluminum oxide (Al₂O₃) layer, a hafnium oxide layer (HfO₂), a zirconium oxide (ZrO₂) layer, a titanium oxide (TiO₂) layer or a combination layer formed of a mixture of at least two metal elements. Alternatively, the first gate insulating layer 104 may be formed of a silicate insulating layer formed of a mixture of a metal element forming the above-mentioned oxide and silicon. The first gate insulating layer 104 may also be formed using an oxide insulating layer device applicable as a material for a gate insulating layer in the manufacture of the conventional oxide thin film transistor. The first gate insulating layer 104 may be formed of an organic insulator thin film having excellent insulation characteristics to ensure or improve flexibility of the material.

The source and drain electrodes 106 may be formed of a transparent conductive thin film. For example, the source and drain electrodes 106 may be formed of ITO or a conductive oxide thin film having a similar conductivity and transparency to ITO. In some cases, according to the characteristics required for an application system of the memory thin film transistor suggested by the present invention, the source and drain electrodes 106 may be formed of a metal thin film used in the manufacture of the conventional thin film transistor.

Here, the source and drain electrodes 106 may be formed in two electrically isolated regions on the first gate insulating layer 104 at predetermined intervals, and a region between the source and drain electrodes is defined as a channel region of the memory thin film transistor. Accordingly, a channel width and length of the memory thin film transistor is determined by a pattern width and a distance between patterns of the source and drain electrodes 106. The channel width and length may be suitably designed with the operating characteristic of the memory transistor.

The channel layer 108A is formed between the source and drain electrodes 106, that is, in the channel region of the memory thin film transistor, to cover sidewalls and parts of top surfaces of the source and drain electrodes 106.

Here, the channel layer 108A serves as a semiconductor of the memory thin film transistor. The channel layer 108A may be formed of an oxide semiconductor, and is preferably formed of a transparent oxide semiconductor thin film which has a wide energy bandgap that serves as a transparent oxide in a visible wavelength range and has semiconductor properties in an electrical aspect. For example, the channel layer 108A may be formed of zinc oxide (ZnO), indium-gallium-zinc oxide (In—Ga—Zn—O), zinc-tin oxide (Zn—Sn—O), or an oxide including at least two elements selected from Zn, In, Ga, Sn and Al. In addition, the channel layer 108A may be formed by doping various elements to the above-mentioned oxide.

The passivation layer 110A serves to prevent damage to the channel layer 108A in a subsequent process, and improve the characteristics of the memory thin film transistor. Here, the passivation layer 110A may be formed on the channel layer 108A, in the channel region between the source and drain electrodes 106 with the channel layer 108A to cover the sidewalls and parts of the top surfaces of the source and drain electrodes 106.

Here, roles of the passivation layer 110A will be described in detail.

First, the passivation layer 110A inhibits process degradation of the channel layer 108A during etching of the channel layer 108A and removal of an etch mask. When the etching and removal of the etch mask are performed without the passivation layer 110A, chemicals such as a photoresist, a photoresist developing solution and a photoresist stripping solution may directly act on the channel layer 108A, and thus degrade the characteristics of a material for the channel layer 108A. For this reason, when the passivation layer 110A is formed on the channel layer 108A, it can prevent chemical degradation of the channel layer 108.

Second, as the passivation layer 110A prevents the channel layer 108A from being damaged or degraded during formation of the second gate insulating layer 112A, the channel layer 108A serves faithfully as a semiconductor so that the memory transistor has favorable operating characteristics.

For example, when the second gate insulating layer 112A is formed of an organic ferroelectric, the organic ferroelectric layer may be formed by a coating process using an organic solution. Here, according to the kind of an organic solution to be used, the characteristics of a material for the channel layer 108A may be degraded. Thus, as the passivation layer 110A may be formed on the channel layer 108A, it can prevent the chemical degradation of the channel layer 108A.

Third, an electrical characteristic of the channel layer 108A may be changed by changing the kind of a material for the passivation layer 110A and processing conditions for forming the passivation layer. For example, as the channel layer 108A is changed in carrier concentration and chemical state of its surface by altering the processing conditions in the formation of the passivation layer 110A, operating characteristics of the memory thin film transistor may be improved.

Fourth, a leakage current of the second gate insulating layer 112A may be inhibited using the passivation layer 110A. For example, when the second gate insulating layer 112A is formed of an organic ferroelectric, the organic ferroelectric layer is greatly increased in leakage current according to progression of thinning because of the characteristic of the material itself. Thus, the operating characteristics of the memory thin film transistor are degraded. Such degradation in characteristics of the memory thin film transistor caused by the leakage current can be prevented by interposing the passivation layer 110A between the second gate insulating layer 112A formed of an organic ferroelectric and the channel layer 108A.

Considering the roles of the passivation layer 110A described above, the passivation layer 110A may be formed of a material which can sufficiently inhibit the process degradation of the channel layer 108A, improve the operating characteristics of the memory transistor, and ensure the electrical characteristic to sufficiently inhibit a leakage current of the second gate insulating layer 112A.

Thus, the passivation layer 110A may be formed of an oxide insulator thin film. For example, the passivation layer 110A may be formed of a silicon-based insulating layer such as a SiO₂ layer, a SiNx layer or a SiON layer, an Al₂O₃ layer, a HfO₂ layer, a ZrO₂ layer, a TiO₂ layer or a combination having a mixture of at least two metal elements. Alternatively, the passivation layer 110A may be formed of a silicate insulating layer in which a metal element forming one of the above-mentioned oxides is mixed with silicon. The passivation layer 110A may also be formed of a material for an oxide insulating layer capable of being used as a material for a gate insulating layer in the manufacture of the conventional oxide thin film transistor.

The second gate insulating layer 112A may be used as a main gate insulating layer to implement a memory operation of the memory thin film transistor, and preferably formed of an organic ferroelectric showing residual polarization due to application of a voltage to an organic material such as a small molecular or high molecular organic material.

For example, the second insulating layer 112A may be formed of poly(vinylidene fluoride) [P(VDF)] and a copolymer [P(VDF-TrFE)] in which trifluorotethylene (TrFE) is mixed with P(VDF) in an appropriate ratio. The mixing composition range of P(VDF) and TrFE may be controlled within the range at which the P(VDF-TrFE) exhibits ferroelectricity. For example, the P(VDF) may be included at 55% or more. Preferably, the mixing composition range may be controlled within the appropriate ratio for optimizing the leakage current characteristic and ferroelectricity of the second gate insulating layer 112A.

The source and drain electrode pads 116 are electrically connected with the source and drain electrode layers 106 by contact plugs 114 formed through the second gate insulating layer 112A. Here, the source and drain electrode pads 116 may be formed of a transparent conductive thin film, for example, ITO or a conductive oxide thin film having a similar conductivity and transparency to ITO. In some cases, according to the characteristics required for an application system of the memory thin film transistor suggested by the present invention, the source and drain electrode pads 116 may be formed of a metal thin film used in the manufacture of the conventional thin film transistor.

A second gate electrode 118 may be disposed on a part of a top surface of the second gate insulating layer 112, particularly, on the channel region of the memory thin film transistor. Here, the second gate electrode 118 may be formed of a transparent conductive thin film, for example, ITO or a conductive oxide thin film having a similar conductivity and transparency to ITO. In some cases, according to the characteristics required for an application system of the memory thin film transistor suggested by the present invention, the second gate electrode 118 may be formed of a metal thin film used in the manufacture of the conventional thin film transistor.

FIG. 2B is a cross-sectional view of a non-volatile memory thin film transistor having a double gate structure according to a second exemplary embodiment of the present invention, in which source and drain electrodes are formed after a channel layer is formed. However, overlapping matters with the description of the first exemplary embodiment will be omitted.

As described above, the memory thin film transistor includes a first gate electrode 202 formed on a substrate 200, a first gate insulating layer 204, a channel layer 206, a passivation layer 208, source and drain electrodes 210, a second gate insulating layer 212, source and drain electrode pads 216 connected with the source and drain electrodes 210 by contact plugs 214 through the second gate insulating layer 212, and a second gate electrode 218.

According to the second exemplary embodiment, after the channel layer 206 and the passivation layer 208 are formed, the source and drain electrodes 210 are formed to cover sidewalls and parts of top surfaces of the channel layer 206 and the passivation layer 208.

According to the structure described in the second exemplary embodiment, a device structure conventionally used in the art to manufacture a bottom gate-type thin film transistor may also be applied to the source and drain electrodes 210, and thus facility investment can be minimized, and a burden to develop new processes can be reduced.

Meanwhile, when the source and drain electrodes 210 are formed after the formation of the channel layer 206, it is likely to degrade the channel layer 206 in a subsequent process. However, as the passivation layer 208 is formed on the channel layer 206 according to the present invention, the degradation of the channel layer 206 in the subsequent process can be prevented. In other words, the passivation layer 208 formed on the channel layer 206 according to the second exemplary embodiment plays other roles than those of the passivation layer 208 described in the first exemplary embodiment.

First, the passivation layer 208 may prevent the process degradation of the channel layer 206, and thus prevent degradation of the characteristics of a material for the channel layer 206 during patterning of the source and drain electrodes 210 by wet or dry etching.

Second, the passivation layer 208 may serve as an etch stop layer during the etching process for patterning the source and drain electrodes 210.

Considering such roles of the passivation layer 208, the passivation layer 208 may be formed of a material capable of sufficiently inhibiting the process degradation of the channel layer 206. In addition, to faithfully serve as an etch stop layer, the passivation layer 208 may be formed of a material having a sufficient etch selectivity between upper and lower layers. In other words, the passivation layer 208 may be formed of a high etch selectivity to the material for the source and drain electrodes 210.

For this reason, the passivation layer 208 may be formed of an oxide insulator thin film. For example, the passivation layer 208 may be formed of a silicon-based insulating layer such as a SiO₂ layer, a SiNx layer or a SiON layer, an Al₂O₃ layer, a HfO₂ layer, a ZrO₂ layer, a TiO₂ layer, or a combination having a mixture of at least two metal elements. Alternatively, the passivation layer 208 may be formed of a silicate insulating layer in which a metal element forming one of the above-mentioned oxides is mixed with silicon. The passivation layer 208 may also be formed of an oxide insulating layer capable of being used as a material for a gate insulating layer in the manufacture of the conventional oxide thin film transistor. The passivation layer 208 may simultaneously use the material capable of being used for the passivation layer 110A described in the first exemplary embodiment.

According to the first and second exemplary embodiments described above, a non-volatile memory thin film transistor having a double gate structure having flexibility, transparency, or both the characteristics, and serving as a memory device may be provided.

Hereinafter, methods of manufacturing non-volatile memory thin film transistors having a double gate structure according to the first and second exemplary embodiments of the present invention will be described with reference to the accompanying drawings.

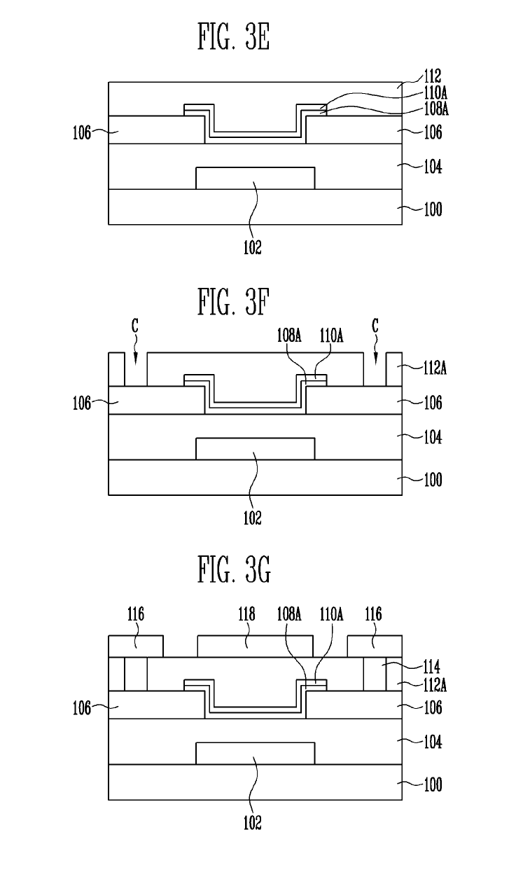

FIGS. 3A to 3G are cross-sectional views illustrating a method of manufacturing the non-volatile memory thin film transistor having a double gate structure according to the first exemplary embodiment of the present invention. Now, a method of manufacturing the memory thin film transistor having the structure described with reference to FIG. 2A will be described.

As shown in FIG. 3A, a substrate 100 is prepared. Here, the substrate 100 may be a glass or plastic substrate. The plastic substrate 100 may be provided after appropriate pretreatment to improve smoothness of the substrate 100. The plastic substrate 100 may be provided after an appropriate process of manufacturing a substrate is performed to improve a thermal resistance characteristic of the substrate 100.

Subsequently, a conductive layer for a first gate electrode is formed on the substrate 100 and patterned, thereby forming a first gate electrode 102. Here, the conductive layer for the first gate electrode may be formed by sputtering, and the patterning may be performed by wet or dry etching. Further, the first gate electrode 102 may be formed to a thickness of 100 to 200 nm.

Subsequently, a first gate insulating layer 104 is formed on the entire structure of the result having the first gate electrode 102. Here, the first gate insulating layer 104 may be formed by a method of forming a thin film used in a conventional process of manufacturing a semiconductor, for example, sputtering, chemical vapor deposition (CVD), or atomic layer deposition (ALD). Meanwhile, a thickness of the first gate insulating layer 104 may be selected appropriate to the characteristics required for the memory thin film transistor having a double gate structure. In other words, the thickness of the first gate insulating layer 104 may be selected to satisfy a turn-on voltage for operating the thin film transistor and a drain current under the condition of applying a control voltage.

Subsequently, a conductive layer for source and drain electrodes is formed on the first gate insulating layer 104 and patterned, thereby forming source and drain electrodes 106. Here, the conductive layer for the source and drain electrodes may be formed by sputtering, and the patterning may be performed by wet or dry etching. Further, the source and drain electrodes 106 may be formed to a thickness of 100 to 200 nm.

As shown in FIG. 3B, a material layer 108 for a channel is formed along the entire surface of the result having the source and drain electrodes 106. In the exemplary embodiment, the case in which the material layer 108 for the channel is formed of an oxide semiconductor, which is transparent in a visible wavelength range, will be described.

Here, a thickness of the material layer 108 for the channel is one of critical device variables determining an operating condition of the memory thin film transistor, and thus may be determined under consideration of the following matters:

First, the thickness of the material layer 108 for the channel is determined in the range that the operating characteristics of the memory thin film transistor can be ensured. Generally, to serve as a semiconductor thin film in a channel region of the thin film transistor, the material layer 108 for the channel may be formed to a thickness of 5 to 50 nm.

When the thickness of the material layer 108 for the channel is less than 5 nm, an average traveling distance of carriers traveling on a surface of the channel layer is less than the layer thickness, and thus carrier mobility can be greatly reduced. Meanwhile, when the thickness of the material layer 108 for the channel is greater than 50 nm, a carrier concentration in the channel layer is too high, causing an increase in off current and a decrease in on/off-operating margin of the transistor in terms of the electrical operating characteristic of the thin film transistor. When the carrier concentration is extremely high, a driving transistor cannot be operated. Considering the first matter, the material layer 108 for the channel may be formed to a thickness of 5 to 50 nm.

Second, the thickness of the material layer 108 for the channel is determined for a memory operation of the memory thin film transistor to be performed at a lower voltage. In the specification, the description of quantitative calculation for determining the operating voltage of the memory transistor is omitted, but the memory transistor requires a higher operating voltage for an off-write operation (e.g., storing data “0”) than for an on-write operation (e.g., storing data “1”). This is because when the channel layer is formed of an oxide semiconductor, unlike a conventional silicon semiconductor operated in an inversion layer and an accumulation layer according to the change in applied voltage, due to the characteristic of the material, the channel layer is operated in a depletion layer and an accumulation layer according to the change in applied voltage, and the oxide semiconductor thin film is completely depleted under a specific voltage condition to behave as an insulator. Under such a condition, in a gate-stack structure forming the memory transistor, loss of a write voltage occurs due to a series capacitor formed by the presence of a complete depletion layer of the oxide semiconductor thin layer. As a result, the operating voltage is increased in the off-write operation. Therefore, to inhibit such an effect in a practical level and reduce the write voltage in the off-write operation, the thickness of the complete depletion layer of the channel layer needs to be reduced as much as possible, which means that the thickness of the material layer 108 for the channel needs to be reduced as much as possible. Consequently, considering the second matter, the material layer 108 for the channel may be formed to a thickness of 20 nm or less.

As a result, considering the first and second matters simultaneously, the material layer 108 for the channel is preferably formed to a thickness of 5 to 20 nm.

The material layer 108 for the channel may be formed by any method conventionally used to form an oxide thin film, for example, sputtering, CVD, ALD, pulsed-laser deposition, spin-coating using a sol-gel solution, or printing using a precursor ink. These methods may be used in combination or modification.

As shown in FIG. 3C, a material layer 110 for a passivation layer is formed on the material layer 108 for the channel. Here, a thickness of the material layer 110 for the passivation layer is one of the critical device variables determining operating characteristics of the memory thin film transistor, and thus may be determined considering the following matters:

First, the thickness of the material layer 110 for the passivation layer should be set in the range in which an operating voltage of the memory transistor is not excessively increased. When the material layer 110 for the passivation layer is too thick, a part of the driving voltage of the memory transistor is consumed by the series capacitor formed by the passivation layer forming a part of the gate-stack structure of the transistor, resulting in an increase in operation voltage in general. Thus, considering the first matter, the material layer 110 for the passivation layer may be formed to a thickness of 10 nm or less.

Second, the thickness of the material layer 110 for the passivation layer should be set in the range in which the process degradation caused by various chemicals can be sufficiently inhibited during the etching of the material layer 108 for the channel.

Third, the material layer 110 for the passivation layer should be set in the range in which a leakage current of the second gate insulating layer to be formed in a subsequent process can be sufficiently inhibited.

Thus, considering the second and third matters, the material layer 110 for the passivation layer may be formed to a thickness of 4 nm or more, and preferably, considering the first to third matters simultaneously, the material layer 110 for the passivation layer is formed to a thickness of 4 to 10 nm.

The material layer 110 for the passivation layer may be formed by any deposition method conventionally used to form an oxide thin film, for example, sputtering, CVD, ALD, pulsed-laser deposition, spin-coating using a sol-gel solution, or printing using a precursor ink. These methods may be used in combination or modification. Particularly, the method of forming the material layer 110 for the passivation layer may be determined by a processing temperature, a use of plasma, and a source material for a thin film not to degrade the characteristics of the material layer 108 for the channel formed below. It is preferable that the processes of forming the material layer 108 for the channel and the material layer 110 for the passivation layer are continuously performed in the same equipment to obtain a high-quality interface.

As shown in FIG. 3D, the material layer 108 for the channel and the material layer 110 for the passivation layer are etched to form a channel layer 108A and a passivation layer 110A on the channel region of the memory thin film transistor.

Here, the process of etching the material layer 110 for the passivation layer and the material layer 108 for the channel may be performed by conventional photolithography. For example, wet etching may be performed using a predetermined wet etching solution, or dry etching may be performed using plasma. During the etching process, the passivation layer 110A effectively prevents degradation of the channel layer 108A.

As shown in FIG. 3E, a second gate insulating layer 112 is formed on the entire structure of the result having the channel layer 108A and the passivation layer 110A. In the exemplary embodiment, the case in which the second gate insulating layer 112 is formed of an organic ferroelectric will be described.

Here, the second gate insulating layer 112 may be formed by spin coating. For example, to form the second gate insulating layer 112 using P(VDF-TrFE), conventionally, a source solution may be prepared by dissolving a solid grain-type P(VDF-TrFE) source in an appropriate organic solvent. A conventional order of forming the second gate insulating layer 112 by spin coating is as follows: first, the source solution is dropped on a predetermined substrate to coat it with spin coating conditions, and annealed at a predetermined temperature to volatilize the organic solvent included in the source solution. Subsequently, annealing is performed at a predetermined temperature to crystallize an organic ferroelectric layer. Generally, the annealing temperature for volatilizing the organic solvent may vary according to an organic solvent to be used, but is preferably 50 to 120° C. The annealing temperature for crystallization may also vary depending on the kind of an organic ferroelectric to be used. When P(VDF-TrFE) is used as an organic ferroelectric material, the annealing temperature is preferably 120 to 160° C. Here, since crystallization of a thin film is essential for the second gate insulating layer 112 to have a good ferroelectric characteristic, it is very important to select the crystallization temperature. If the crystallization temperature is too low, the thin film has low crystallinity and thus a desired electrical characteristic is difficult to obtain. On the other hand, if the crystallization temperature is too high, the thin film completely melts and thus is likely to lose ferroelectricity.

Meanwhile, when the second gate insulating layer 112 is formed by spin coating, a thickness of the second gate insulating layer 112 may be controlled by controlling the number of times spin coating is performed and a concentration of the organic ferroelectric source solution. Here, to select the appropriate thickness of the second gate insulating layer 112, the following two matters should be considered:

First, the thickness of the second gate insulating layer 112 may be selected to reduce the operating voltage of the memory transistor as much as possible. To this end, it is preferable that the thickness of the second gate insulating layer 112 is reduced as much as possible to easily invert polarization at a relatively low applied voltage. However, the conventional research reveals that when the organic ferroelectric thin film has a predetermined thickness or less, the ferroelectricity of the thin film is greatly degraded, thereby greatly increasing an electric field value at which polarization is inverted, and the time for the polarization inversion in the same electric field becomes much longer. While a critical thickness of the layer at which such degradation occurs may be changed depending on which electrodes are used for upper and lower portions of the organic ferroelectric, it has been known that, generally, the degradation is noticeably observed at a thickness of 50 nm or less.

Second, the thickness of the second gate insulating layer 112 may be selected to improve the memory transistor, particularly, data retention of the memory transistor. Since the data retention time of the memory transistor is very closely tied to the leakage current of the second gate insulating layer 112, it is necessary to optimize a deposition thickness of the second gate insulating layer 112 not to have excessive leakage current during the operation of the device. According to the research, it has been known that when the thickness of the organic ferroelectric layer is about 200 nm, no significant leakage current is caused by the applied voltage.

As a result, considering the first and second matters, the deposition thickness of the second gate insulating layer 112 may be selected within the range of 50 to 200 nm. However, though the organic ferroelectric layer will become thinner according to future development of technology, the lower limit of the deposition thickness of the second gate insulating layer 112 may be lower with development of a method of obtaining excellent ferroelectricity.

As shown in FIG. 3F, contact holes C partially exposing the surfaces of the source and drain electrodes 106 are formed by partially etching the second gate insulating layer 112. In FIG. 3F, the second gate insulating layer etched during the formation of the contact holes C is indicated as reference numeral “112A.”

For example, the contact holes C may be formed by forming a photoresist pattern on the second gate insulating layer 112, etching the organic ferroelectric second gate insulating layer 112 using the photoresist pattern as an etch mask, and removing the photoresist pattern being an etch mask. Here, in the formation of the contact holes C, two matters should be considered.

First, when the second gate insulating layer 112 is etched using oxygen plasma, conditions of the oxygen plasma should be optimized not to degrade the characteristics of the channel layer 108A. Generally, characteristics of the surface and inside of the thin film of the channel layer 108A formed of an oxide semiconductor are likely to be considerably changed by the plasma treatment. While the channel layer 108A is protected by the passivation layer 110A during the etching of the second gate insulating layer 112, it is necessary to optimize the oxygen plasma condition to prevent degradation in characteristics of the channel layer 108A.

Second, a stripping solution which does not have an effect on the characteristics of the second gate insulating layer 112A during the stripping of the photoresist pattern used as the etch mask should be selected. Since chemicals generally used to strip the photoresist pattern can have a fatal effect on the characteristics of the second gate insulating layer 112A, the stripping solution is very carefully selected. Moreover, since the removal of the photoresist pattern adopts a kind of dry etching using plasma in a vacuum unlike common wet etching, the photoresist pattern is cured more so that the photoresist pattern may partially remain on the second gate insulating layer 112A during the stripping under inappropriate conditions.

The stripping solution applicable to the process has the following characteristics:

First, ingredients of the stripping solution should not have a chemical effect on the second gate insulating layer 112A. For example, when the organic ferroelectric thin film is formed of P(VDF-TrFE), the ingredients of the stripping solution should not chemically decompose the P(VDF-TrFE) so as to cause the removal of the thin film. Though the P(VDF-TrFE) is not removed, the stripping solution should not greatly change the crystalline state or chemical bond of the P(VDF-TrFE), which would cause serious change in electrical characteristics of the P(VDF-TrFE). For example, since an organic chemical generally applied to strip the photoresist pattern, acetone, serves to completely dissolve the P(VDF-TrFE) to remove it, it is impossible to use the acetone as the stripping solution in the method of the present invention.

Second, the corresponding stripping solution can completely remove a residual component of the photoresist pattern. If not, the residual component of the photoresist pattern remaining on a part of the substrate 100 having the device of the present invention could possibly cause hindrance of normal operation of the device of the present invention. For example, while an organic chemical containing methanol as a main component may be used to strip the photoresist pattern, depending on the kind of the photoresist pattern used herein and the effect of the preceding process, the residual component of the photoresist may not be completely removed by methanol.

As shown in FIG. 3G, a conductive layer is formed on the entire structure of the result having the contact holes C. Here, the conductive layer fills the contact holes C, thereby forming contact plugs 114 connected to the source and drain electrodes 106, respectively.

Subsequently, the conductive layer is etched, thereby forming source and drain electrode contact pads 116 respectively connected to the source and drain electrodes 106 through contact plugs 114, and a second gate electrode 118 disposed on the channel region of the memory transistor.

Here, the conductive layer may be deposited by sputtering. The conductive layer may be formed of a metal conductive thin film which is not transparent but conventionally used depending on the application of the memory thin film transistor, and may be deposited by a predetermined method conventionally used. The deposited conductive layer may be patterned by an etching process suitable for the kind of the material for the deposited conductive layer.

Here, the formation and patterning of the contact plugs 114, the source and drain electrode pads 116, and the second gate electrode 118 should be performed under conditions that do not damage the underlying second gate insulating layer 112A. The reasons thereof are as follows:

First, the conventional deposition of the conductive layer using plasma is likely to considerably degrade electrical and mechanical characteristics of the second gate insulating layer 112A formed of the organic ferroelectric.

Second, the second gate insulating layer 112A can be degraded during the formation of the second gate electrode 118. When the conductive oxide thin film is used to form the second gate electrode 118, subsequent annealing is frequently performed at a predetermined temperature after the deposition to improve conductivity of the electrode. Thus, the annealing should be performed at a lower temperature than the melting point of the second gate insulating layer 112A.

Third, the etching of the second gate electrode 118 can provide a poor patterning profile. Due to a very high surface roughness, the P(VDF-TrFE) used in the formation of the second gate insulating layer 112A is not sufficiently close to the conductive oxide thin film conventionally used, and thus the second gate electrode 118 may be poorly patterned.

For this reason, it is preferable to optimize the kind of the material for the electrode, the deposition method, the subsequent annealing temperature, and the etching conditions to prevent damage of the second gate insulating layer 112A and easily form the shape of the source and drain electrode pads 116 and the second gate electrode 118.

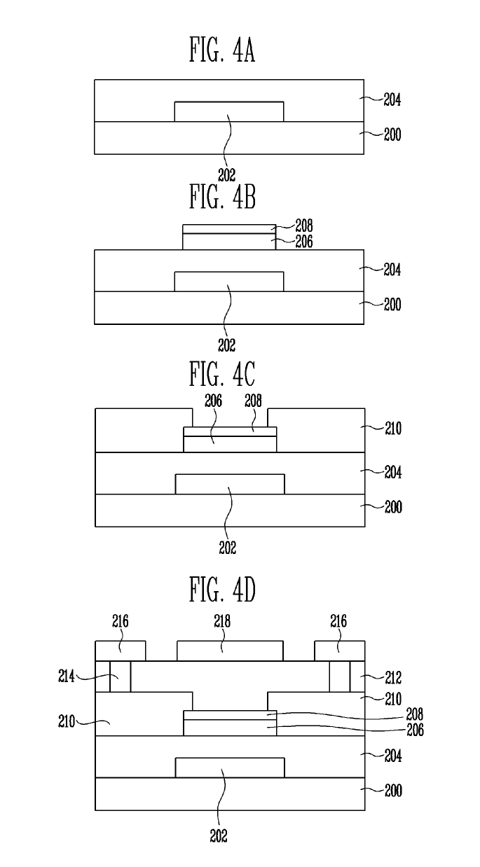

FIGS. 4A to 4D are cross-sectional views illustrating a method of manufacturing the non-volatile memory thin film transistor having a double gate structure according to the second exemplary embodiment of the present invention. In detail, the method of manufacturing the memory thin film transistor having the structure described with reference to FIG. 2B will be described. However, overlapping parts with the description of the first exemplary embodiment will be omitted.

As shown in FIG. 4A, a conductive layer for a first gate electrode is formed on a substrate 200 and etched, thereby forming a first gate electrode 202. Subsequently, a first gate insulating layer 204 is formed on the entire structure of the result having the first gate electrode 202.

The process performed so far is the same as described in the first exemplary embodiment.

As shown in FIG. 4B, a material layer for a channel and a material layer for a passivation layer are sequentially formed along the entire surface of the result having the first gate insulating layer 204 and etched, thereby forming a channel layer 206 and a passivation layer 208 on a channel region of the memory thin film transistor.

As shown in FIG. 4C, a conductive layer for source and drain electrodes are formed on the entire structure of the result having the channel layer 206 and the passivation layer 208 and etched, thereby forming source and drain electrodes 210.

As shown in FIG. 4D, a second gate insulating layer 212 is formed on the entire structure of the result having the source and drain electrodes 210 and partially etched, thereby forming contact holes partially exposing surfaces of the source and drain electrodes 210.

Subsequently, a conductive layer is formed on the entire surface of the result having the contact holes and etched, thereby forming contact plugs 214 filling the contact holes, source and drain electrode pads 216 respectively connected to the source and drain electrodes 210 by the contact plugs 214, and a second gate electrode 218.

The method of manufacturing the memory thin film transistor having a double gate structure according to the first or second exemplary embodiment is provided as an example, and thus the present invention is not limited thereto. In addition, the most appropriate specific processing conditions for the structure of the entire system to be applied and required processes may be selected.

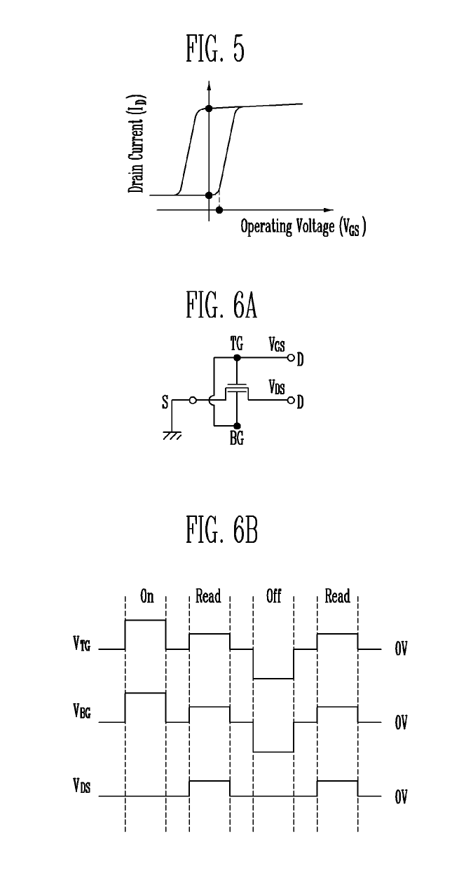

FIG. 5 is a graph showing the relationship between a drain current and a gate voltage of a memory thin film transistor having a double gate structure manufactured according to an exemplary embodiment of the present invention.

As described above, the double gate structure is applied to the memory thin film transistor. Thus, as a control voltage is applied to first gate electrode 102 or 202 of the memory thin film transistor, a turn-on voltage may be easily controlled.

Particularly, the graph shows the case in which the turn-on voltage is generated in a positive voltage region by applying a negative voltage to the first gate electrode 102 or 202 during driving of the memory thin film transistor. Here, the following matters may be considered to set the turn-on voltage.

First, the turn-on voltage of the memory thin film transistor may be set at a gate voltage of 0 V not to generate a drain current during turn-off of the memory thin film transistor. Though not shown in the graph, even if the memory thin film transistor is turned on, the turn-on voltage may be set in a positive voltage region not to generate the drain current at a gate voltage of 0V. Therefore, the problem of generating the drain current at a gate voltage of 0V, which is caused by forming the turn-on voltage of the memory thin film transistor in a negative voltage region, can be resolved.

Second, the turn-on voltage may be set to symmetrically apply an on/off-operating voltage during a write operation of the memory thin film transistor. In other words, a memory window width of the drain current set by the write operation is set on the basis of a gate voltage of 0V. As a result, a circuit can be prevented from becoming complicated due to asymmetry between the on-operating voltage and the off-operating voltage.

Third, the turn-on voltage of the thin film transistor is set to perform a read operation at a gate voltage of 0V. Thus, a voltage level is maintained as low as possible, and a data retention characteristic can be improved.

Hereinafter, a method of driving a memory thin film transistor capable of dynamically controlling a turn-on voltage thereof will be described under consideration of the above-mentioned three matters.

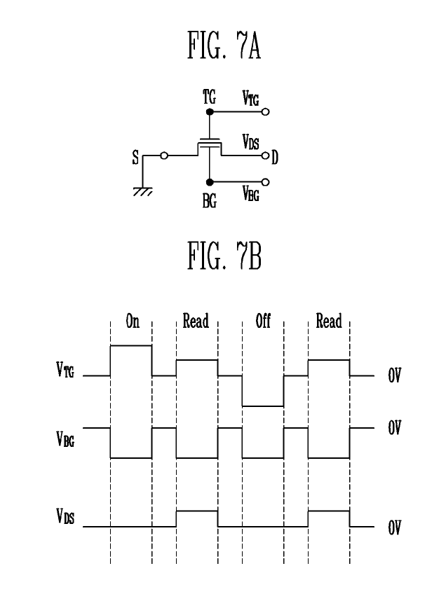

FIGS. 6A and 6B are a circuit diagram and a timing diagram, which illustrate a first method of driving a memory thin film transistor having a double gate structure according to an exemplary embodiment of the present invention.

As shown in FIG. 6A, as a first gate terminal BG connected to a first gate electrode 102 or 202 is connected to a second gate terminal TG connected to a second gate electrode 118 or 218, the driving of the memory thin film transistor may be controlled by a single gate signal. In other words, a memory thin film transistor is driven by applying the same operating voltage V_{GS} to the first and second gate terminals BG and TG

Likewise, the memory thin film transistor may have a high driving current, a decreased subturn-on voltage slope, and a high field effect mobility by introducing a double gate structure and applying the same operating voltage V_{GS} to the first and second gate electrodes 102, 202, 118 and 218. As a result, the memory thin film transistor is increased in performance, and thereby a memory device favorable in a low voltage operation and having an increased operating voltage of a circuit can be provided.

FIG. 6B shows a timing diagram of the first driving method according to the exemplary embodiment of the present invention. Here, “V_{TG}” indicates a potential of the second gate electrode 118 or 218, “V_{BG}” indicates a potential of the first gate electrode 102 or 202, and “V_{DS}” indicates a potential of the drain electrode.

In an on-write operation of the memory thin film transistor (e.g., storing data “1”), a predetermined positive write voltage V_{GS} is simultaneously applied to both the first gate electrode 102 or 202 and the second gate electrode 118 or 218, and the drain voltage V_{DS} is fixed as a ground voltage. As a result, the on-write operation is completed.

In an off-write operation of the memory thin film transistor (e.g., storing data “0”), a predetermined negative write voltage V_{GS} is simultaneously applied to both the first gate electrode 102 or 202 and the second gate electrode 118 or 218, and the drain voltage V_{DS} is fixed as a ground voltage. As a result, the off-write operation is completed.

In the read operation to read data stored in the memory thin film transistor, a predetermined read voltage V_{GS} is simultaneously applied to the first gate electrode 102 or 202 and the second gate electrode 118 or 218, and a predetermined drain voltage V_{DS} is applied to the drain electrode. Here, the stored data is read by detecting a level of a current flowing in the memory thin film transistor. In the timing diagram, a positive read voltage V_{GS} is applied during the read operation, but it is merely an exemplary embodiment. Thus, the read voltage may be set as a negative voltage or ground voltage according to the operation characteristic of the memory thin film transistor.

When the first driving method is applied to the memory thin film transistor having a double gate structure, the memory thin film transistor is driven using two channel layers, including a channel layer formed on a bottom surface of a channel layer 108A or 206 in contact with the first gate insulating layer 104 or 204 and the channel layer 108A or 206 and a channel layer formed on an top surface of the channel 108A or 206 in contact with the second gate insulating layer 112A or 212 and the channel layer 108A or 206. Thus, though width and length of a channel of the device are not controlled, a drain current substantially flowing in both the channel layers may be used as a driving current of the transistor. As a result, the memory transistor having a double gate structure of the present invention may obtain a high driving current characteristic.

Particularly, according to the present invention, though the width and length of the channel determining a size of the device are not adjusted, a high drain current can be ensured, resulting in improvement in field effect and mobility of the memory thin film transistor. In addition, using an organic ferroelectric insulating layer having a relatively high permittivity as the second gate insulating layer 112A or 212, an additional field effect and improvement of mobility can be obtained.

Since a drain current value capable of being ensured by applying the first driving method to the memory thin film transistor of the present invention is determined by gate capacity values of the first gate insulating layer 104 or 204 and the second gate insulating layer 212A or 212, and a turn-on voltage characteristic determined by charges applied to the respective channel layers, it is necessary to precisely design each device variable to maximize a drain driving current.

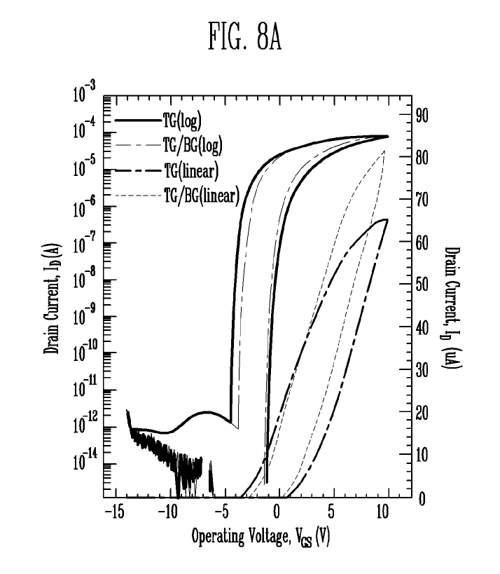

FIGS. 7A and 7B are a circuit diagram and a timing diagram, which illustrate a second method of driving a memory thin film transistor having a double gate structure according to an exemplary embodiment of the present invention.

As shown in FIG. 7A, the memory thin film transistor is driven by controlling a first gate electrode 102 or 202 and a second gate electrode 118 or 218 using a first gate terminal BG connected to the first gate electrode 102 or 202 and a second gate terminal TG connected to the second gate electrode 118 or 218, respectively. In other words, the memory thin film transistor is driven by applying signals to the first and second gate terminals BG and TG, respectively.

In detail, when a control voltage V_{BG} having a predetermined value is applied to the first gate electrode BG, an operating voltage V_{TG} is applied to the second gate electrode TG, thereby driving the memory thin film transistor having a double gate structure.

FIG. 7B is a timing diagram of the second driving method according to the exemplary embodiment of the present invention. Here, “V_{TG}” indicates a potential of the second gate electrode 118 or 218, “V_{BG}” indicates a potential of the first gate electrode 102 or 202, and “V_{DS}” indicates a potential of the drain electrode.

In an on-write operation of the memory thin film transistor (e.g., storing data “1”), when a predetermined negative control voltage V_{BG} is applied to the first gate electrode 102 or 202, a predetermined positive operating voltage V_{TG} is applied to the second gate electrode 118 or 218. Here, the drain electrode is grounded. A level of the control voltage V_{BG} for controlling a turn-on voltage of the memory thin film transistor is determined by an operating characteristic of the memory transistor.

In an off-write operation of the memory thin film transistor (e.g., storing data “0”), when a predetermined negative control voltage V_{BG} is applied to the first gate electrode 102 or 202, a predetermined negative operating voltage V_{TG} is applied to the second gate electrode 118 or 218. Here, the drain electrode is grounded. Here, a level of the control voltage V_{BG} for controlling the turn-on voltage of the memory thin film transistor is determined by the operating characteristic of the memory transistor.

In a read operation to read data stored in the memory thin film transistor, a predetermined read voltage V_{TG} is applied to the first gate electrode 102 or 202, a predetermined read voltage V_{GS} is applied to the second gate electrode 118 or 218, and a predetermined drain voltage V_{DS} is applied to the drain electrode. Here, the store data is read by detecting a current level flowing in the memory thin film transistor. The timing diagram shows the case in which a positive read voltage V_{GS} is applied in the read operation, which however is merely an exemplary embodiment, and thus the read voltage may be set as a negative voltage or a ground voltage according to the operating characteristic of the memory thin film transistor.

Like this, as the second driving method is applied to the memory thin film transistor having a double gate structure, three expected effects are as follows:

First, the turn-on voltage of the memory thin film transistor can be easily controlled within a predetermined range, and particularly, can be set to be higher or lower than that of the conventional single gate memory thin film transistor.

The control voltage V_{BG} having a regular value may be applied to the first gate terminal BG, thereby controlling a basic potential of the channel layer 108A or 206 according to the potential of the applied control voltage V_{BG}. For example, the turn-on voltage of the memory thin film transistor may be shifted in a positive direction by applying a negative control voltage V_{BG} to the first gate terminal BG In other words, as a control voltage having a negative value is applied to the first gate terminal BG, the memory thin film transistor can have a positive turn-on voltage. In addition, the positive control voltage V_{BG} is applied to the first gate terminal BG, and thereby the turn-on voltage of the memory thin film transistor may be shifted in a negative direction.

Therefore, the turn-on voltage of the memory thin film transistor may be easily controlled by the control voltage V_{BG} applied to the first gate terminal BG. Here, as the turn-on voltage of the memory thin film transistor is formed in a positive voltage region by applying a negative control voltage V_{BG} to the first gate terminal BG, and a memory window width of a drain current generated by the write operation is formed on the basis of a gate voltage of 0V, the entire power consumption of the system may be reduced, a simple driving circuit may be obtained, and a data retention characteristic may be improved.

Second, a write speed of the memory thin film transistor can be improved. The conventional memory thin film transistor using an organic ferroelectric thin film as a gate insulating layer takes relatively long for the write operation. This is not because a polarization inverting speed of the organic ferroelectric material is especially low, but because the polarization inverting speed is significantly changed depending on the level of the applied voltage. Further, it can be estimated that the channel layer of the memory thin film transistor is completely depleted in a predetermined operating voltage condition, so that a compensation charge required for polarization inversion of the gate insulating layer may not be sufficiently provided from the inside of the channel layer.

Thus, during the driving of the memory thin film transistor, the control voltage V_{BG} having a regular value is applied to the first gate terminal BG connected to the first gate electrode 102 or 202, thereby increasing a substantial gate applied voltage between the second gate electrode 118 or 218 and the channel layer 108A or 206. Alternatively, during the driving of the memory thin film transistor, a regular value of a control voltage V_{BG} is applied to the first gate terminal BG, thereby charging a certain amount of charges to the channel layer 108A or 206 through the first gate insulating layer 104 or 204. According to such a driving method, a write speed of the memory thin film transistor may be improved.

Third, performance of the memory thin film transistor can be improved. According to the present invention, when a control voltage V_{BG} having a certain value is applied to the first gate electrode 102 or 202, an operating voltage V_{TG} is applied to the second gate electrode 118 or 218, and thus a substantial level of a voltage applied between the channel layer 118A or 206 and the second gate electrode 118 or 218 can be easily controlled. Accordingly, a level of the voltage applied to the second gate insulating layer 112A or 212 can be easily controlled, and thereby a greater memory operating margin of the memory thin film transistor may be ensured.

To this end, a negative control voltage V_{BG} may be applied to the first gate terminal BG, and thus a turn-on voltage of the memory thin film transistor can be shifted in a positive direction, and application of the memory thin film transistor can be improved.

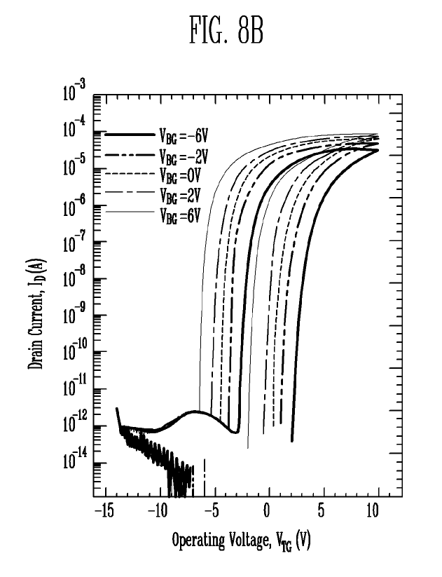

FIGS. 8A and 8B are graphs showing the relationship between a gate voltage and a drain current of a memory thin film transistor having a double gate structure manufactured according to an exemplary embodiment of the present invention.

Here, the device used to measure the characteristic of the memory transistor is manufactured according to the first exemplary embodiment described above, and a detailed manufacturing method is as follows:

A substrate 100 is formed of glass, and a first gate electrode 102 is formed of ITO at a thickness of 150 nm. The first gate insulating layer 104 is formed of Al₂O₃ at a thickness of 65 nm by ALD. Source and drain electrodes 106 are formed of an ITO thin film at a thickness of 150 nm. The channel layer 108A is formed of an indium-gallium-zinc oxide (IGZO) thin film by sputtering at a thickness of 10 nm. A passivation layer is formed of Al₂O₃ at a thickness of 9 nm by ALD at 200° C. A second gate insulating layer 112A is formed of a P(VDF-TrFE) thin film at a thickness of 120 nm. The P(VDF-TrFE) thin film is formed by spin coating, and annealed at 140° C. to crystallize. Contact holes C are formed by oxygen plasma etching using a photoresist as an etch mask. Source and drain electrode pads 116 and a second gate electrode 118 are formed of aluminum thin films.

FIG. 8A shows a drain current measured according to an operating voltage when a memory thin film transistor is driven by the first driving method of the present invention.

Here, “TG” indicates a drain current measured by applying an operating voltage only to the second gate terminal TG, and “TG/BG” indicates a drain current measured by simultaneously applying an operating voltage to a set of the first and second gate terminals BG and TG “log” indicates the measured drain currents expressed on a log scale, and “linear” indicates the measured drain currents expressed on a linear scale.

As shown from the graph, it can be noted that a higher level of the drain current can be ensured by applying the same gate voltage, i.e., an operating voltage V_{TG}, when the memory thin film transistor is driven using both the first and second gate terminals BG and TG than using the second gate terminal TG alone. It can be more apparent as the line TG (linear) expressed on a linear scale is compared with the line TG/BG (linear) expressed on a linear scale. To be specific, when only the second gate terminal TG is used, about 66 μA drain voltage can be obtained by the application of 10V of the operating voltage, but when the set of the first and second gate terminals BG and TG is used, about 82 μA of drain current can be obtained by the application of 10V of gate voltage. As a result, the memory transistor having a double gate structure of the present invention can have improved field effect mobility.

According to the present invention, it can be confirmed that a larger drain current value is ensured using the same operating voltage by inducing the double gate structure to the memory thin film transistor.

FIG. 8B shows a drain current measured according to the operating voltage when a memory thin film transistor is driven by the second driving method of the present invention.

Here, each data line indicates variation of drain current values obtained when an operating voltage V_{TG} in a range of −14 to 10V is applied to a second gate terminal TG in the state in which −6, −2, 0, 2 or 6V of control voltage V_{BG} is applied to a first gate terminal BG.

From the graph, it can be noted that a turn-on voltage of the memory thin film transistor can be controlled according to the level of the control voltage V_{BG} applied to the first gate terminal BG, though a gate voltage applied to the second gate terminal TG, that is, an operating voltage V_{TG}, is set the same within a range of −14 to 10V. Particularly, it can be noted that the turn-on voltage of the memory thin film transistor can be shifted in a negative direction (the narrow line, refer to the dash-dotted line) by applying a positive control voltage V_{BG} to the first gate terminal BG, or in a positive direction (the dash-dot-dotted line, refer to the thick line) by applying a negative control voltage V_{BG} to the first gate terminal BG

Thus, according to the present invention, it is confirmed that the turn-on voltage of the memory thin film transistor can be easily controlled due to the control voltage V_{BG} applied to the first gate electrode 102 or 202.

According to the present invention, a non-volatile memory thin film transistor having a double gate structure is provided, which is formed on a substrate such as a transparent glass substrate or a flexible plastic. The non-volatile memory thin film transistor is physically flexible and transparent in a visible wavelength range.

Particularly, in the non-volatile memory thin film transistor having a double gate structure, a first gate electrode is connected to a second gate electrode, and thereto an operating voltage is applied. Therefore, as compared to the conventional art, a higher driving current can be obtained, and field effect mobility of the memory thin film transistor can be improved.

Further, in the non-volatile memory thin film transistor having a double gate structure, when a control voltage for controlling a turn-on voltage of the transistor to the first gate electrode is applied, the operating voltage is applied to the second gate electrode. Therefore, the turn-on voltage can be easily controlled and write speed and performance of the memory transistor can be improved, resulting in low power consumption and high speed in operation of the memory transistor. Consequently, the present invention can highly contribute to implementation of various flexible and transparent electronics apparatuses in the future.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A non-volatile memory transistor having a double gate structure, comprising:
a first gate electrode formed on a substrate and to which an operating voltage is applied;
a first gate insulating layer formed on the first gate electrode;
source and drain electrodes formed on the first gate insulating layer at predetermined intervals;
a channel layer formed on the first gate insulating layer between the source and drain electrodes;
a second gate insulating layer formed on the channel layer; and
a second gate electrode formed on the second gate insulating layer and connected to the first gate electrode such that the operating voltage is applied thereto.

2. The transistor of claim 1, wherein, during an on-write operation, a positive write voltage is applied to the first and second gate electrodes.

3. The transistor of claim 1, wherein, during an off-write operation, a negative write voltage is applied to the first and second gate electrodes.

4. A non-volatile memory transistor having a double gate structure, comprising:
a first gate electrode formed on a substrate and to which a control voltage for controlling a turn-on voltage of the transistor is applied;
a first gate insulating layer formed on the first gate electrode;
source and drain electrodes formed on the first gate insulating layer at predetermined intervals;
a channel layer formed on the first gate insulating layer between the source and drain electrodes;
a second gate insulating layer formed on the channel layer; and
a second gate electrode formed on the second gate insulating layer and to which an operating voltage is applied when the control voltage is applied to the first gate electrode.

5. The transistor of claim 4, wherein the control voltage having a negative value is applied to the first gate electrode, and the non-volatile memory transistor has a positive turn-on voltage.

6. The transistor of claim 4, wherein, during an on-write operation, a positive write voltage is applied to the second gate electrode when a negative control voltage is applied to the first gate electrode.

7. The transistor of claim 4, wherein, during an off-write operation, a negative write voltage is applied to the second gate electrode when a negative control voltage is applied to the first gate electrode.

8. The transistor of claim 4, wherein, during a read operation, a read voltage is applied to the second gate electrode when a negative control voltage is applied to the first gate electrode.

9. The transistor of claim 1, wherein the channel layer is formed of an oxide semiconductor, which is transparent in a visible wavelength range.

10. The transistor of claim 4, wherein the channel layer is formed of an oxide semiconductor, which is transparent in a visible wavelength range.

11. The transistor of claim 1, wherein the second gate insulating layer is formed of an organic ferroelectric.

12. The transistor of claim 1, further comprising a passivation layer formed on the channel layer.

13. The transistor of claim 1, wherein the channel layer covers sidewalls and parts of top surfaces of the source and drain electrodes.

14. The transistor of claim 1, wherein the source and drain electrodes cover sidewalls and a part of a top surface of the channel layer.

15. The transistor of claim 4, wherein the channel layer is formed of an oxide semiconductor, which is transparent in a visible wavelength range.

16. The transistor of claim 4, wherein the second gate insulating layer is formed of an organic ferroelectric.

17. The transistor of claim 4, further comprising a passivation layer formed on the channel layer.

18. The transistor of claim 4, wherein the channel layer covers sidewalls and parts of top surfaces of the source and drain electrodes.

19. The transistor of claim 4, wherein the source and drain electrodes cover sidewalls and a part of a top surface of the channel layer.
